(19) United States
(12) Patent Application Publication
(10) Pub. No.: US 2026/0334154 A1
(43) Pub. Date: Oct. 22, 2026

(54) ELECTROSTATIC CHUCK

(71) Applicant: TOTO LTD., Fukuoka (JP)

(72) Inventors: Takashi TAMADA, Fukuoka (JP); Jun SHIRAISHI, Fukuoka (JP); Hitoshi SASAKI, Fukuoka (JP)

(73) Assignee: TOTO LTD., Fukuoka (JP)

(21) Appl. No.: 19/468,313

(22) Filed: Feb. 3, 2026

(30) Foreign Application Priority Data
Mar. 17, 2025 (JP) 2025-042649

(51) Int. Cl. H10P 72/72; H02N 13/00

(52) U.S. Cl. CPC H10P 72/722; H02N 13/00

(57) ABSTRACT

An electrostatic chuck 10 includes a dielectric substrate 100 and a base plate 200 joined to the dielectric substrate 100. The dielectric substrate 100 is formed of a material containing alumina as a principal component. The base plate 200 is formed of a material containing aluminum nitride as a principal component.

### CROSS-REFERENCE TO RELATED APPLICATION

This application is based upon and claims the benefit of priority from Japanese Patent Application No. 2025-042649 filed on Mar. 17, 2025, the entire contents of which are incorporated herein by reference.

### FIELD

The present invention relates to an electrostatic chuck.

### BACKGROUND

For example, in a semiconductor manufacturing apparatus including an etching apparatus, an electrostatic chuck is provided as an apparatus configured to attract and hold a wafer such as a silicon wafer to be processed. The electrostatic chuck includes a dielectric substrate inside which an attraction electrode is provided and a base plate which supports the dielectric substrate, and these are joined to each other. When a voltage is applied to the attraction electrode, an electrostatic force is generated, and the wafer placed on the dielectric substrate is attracted and held.

As disclosed in International Publication No. WO 2022/255118, the dielectric substrate is typically formed of a ceramics material such as alumina, for example. On the other hand, the base plate is typically formed of a metallic material such as aluminum, for example, in order to enhance its cooling performance. The dielectric substrate and the aluminum are typically joined to each other via a resin material such as a silicone adhesive, for example.

### SUMMARY

A metallic material is a material having a larger coefficient of linear expansion as compared with a ceramics material. Due to this, when a temperature of the electrostatic chuck increases or decreases in the semiconductor manufacturing apparatus, there is a possibility that peeling (delamination) occurs between the dielectric substrate and the base plate due to the difference in coefficients of linear expansion. Particularly in recent semiconductor manufacturing apparatuses, in order to meet requirements such as multilayering, etching processing has come to be performed in an extremely low-temperature environment. For this reason, it is considered that the above-described peeling problem will become more likely to occur in the future.

The present invention has been made in view of such a problem and aims at providing an electrostatic chuck that can suppress peeling between the dielectric substrate and the base plate.

To address the above-described issue, an electrostatic chuck according to the present invention includes a dielectric substrate including a placement surface on which an object to be attracted is placed, and a base plate joined to the dielectric substrate. The dielectric substrate is formed of a material containing alumina as a principal component. The base plate is formed of a material containing aluminum nitride as a principal component.

Aluminum nitride is a material having a thermal conductivity substantially equal to that of aluminum, but its coefficient of linear expansion is substantially equal to that of alumina. By forming the base plate using aluminum nitride in place of a metallic material as in the related art, it is possible to suppress peeling between the dielectric substrate and the base plate without sacrificing its cooling performance.

According to the present invention, it is possible to provide an electrostatic chuck capable of suppressing peeling between the dielectric substrate and the base plate.

### BRIEF DESCRIPTION OF THE DRAWINGS

FIG. 1 is a cross-sectional view schematically illustrating a configuration of an electrostatic chuck according to a first embodiment;

FIG. 2 is a diagram illustrating respective physical properties of alumina, aluminum, and aluminum nitride;

FIG. 3 is a cross-sectional view schematically illustrating a configuration of an electrostatic chuck according to a second embodiment;

FIG. 4 is an enlarged view of a joining layer of the electrostatic chuck according to the second embodiment;

FIG. 5 is a graph indicating an alumina content and an aluminum nitride content in each part of the joining layer; and

FIG. 6 is an enlarged view of a joining layer of an electrostatic chuck according to a third embodiment.

### DETAILED DESCRIPTION

Hereinafter, the present embodiment will be described with reference to the accompanying drawings. To ease understanding of the descriptions, in each drawing, the same components are denoted by the same reference signs as much as possible, and duplicate descriptions are not repeated.

A first embodiment will be described. An electrostatic chuck 10 according to the present embodiment is configured to attract and hold a wafer W set as a process target by an electrostatic force inside a semiconductor manufacturing apparatus such as, for example, an etching apparatus which is not illustrated in the drawing. The wafer W that is an object to be attracted is, for example, a silicon wafer. The electrostatic chuck 10 may be used in an apparatus other than the semiconductor manufacturing apparatus.

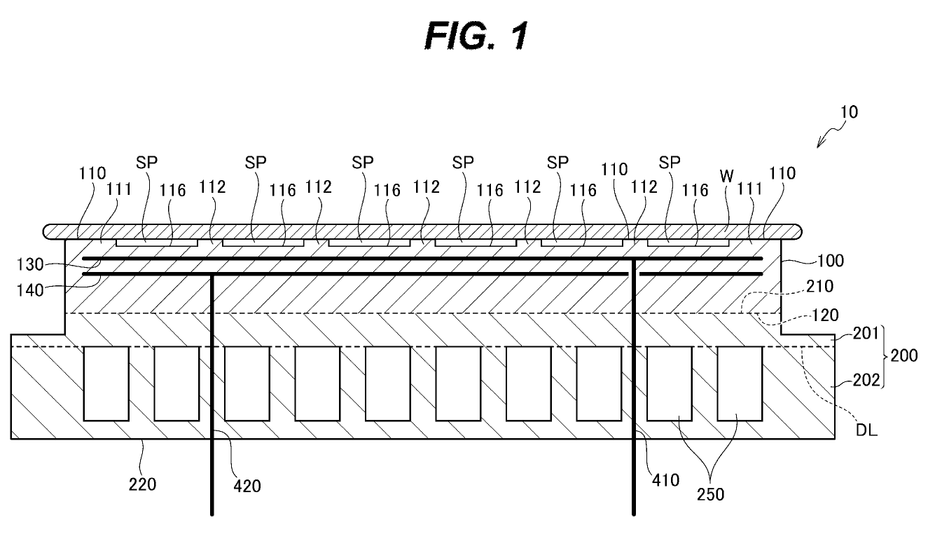

FIG. 1 is a cross sectional view schematically illustrating a configuration of the electrostatic chuck 10 in a state in which the wafer W is attracted and held. The electrostatic chuck 10 includes a dielectric substrate 100 and a base plate 200.

The dielectric substrate 100 is a substantially disk-shaped member formed of a ceramic sintered body. The dielectric substrate 100 is formed of, for example, a material containing highly pure alumina (Al₂O₃) as a principal component. A ceramics purity or type, an additive, or the like in the dielectric substrate 100 may be appropriately set by taking into account plasma resistance or the like needed for the dielectric substrate 100 in the semiconductor manufacturing apparatus.

In the present specification, the term "principal component" refers to a compound that is confirmed to be contained in a target object in a relatively larger amount than any other compound contained therein, when quantitative or semi-quantitative analysis is performed on the target object such as the dielectric substrate 100 by X-ray Diffraction (XRD). A ratio occupied by alumina as the principal component is larger than 50% in the dielectric substrate 100 of the present embodiment. The ratio is more preferably equal to or larger than 90%, and even more preferably equal to or larger than 95%.

When alumina is used as a material of the dielectric substrate 100 as in the present embodiment, it is preferable that a purity of alumina used as a raw material in the dielectric substrate 100 is set to be equal to or larger than 99.5%, or equal to or larger than 99.9%. By increasing the purity of alumina to such a level, it is possible to sufficiently ensure durability of the dielectric substrate 100 against plasma. A volume resistivity of the dielectric substrate 100 is preferably set to be equal to or larger (higher) than 1×10¹⁴ Ω⋅cm in a case of a Coulomb-force type electrostatic chuck, and is preferably set to fall within a range of 1×10⁹ to 1×10¹² Ω⋅cm in a case of a Johnsen-Rahbek-force type electrostatic chuck.

A surface 110 on an upper side in FIG. 1 in the dielectric substrate 100 serves as a "placement surface" on which the wafer W is placed. A surface 120 on a lower side in FIG. 1 in the dielectric substrate 100 serves as a "surface to be joined" which is joined to the base plate 200 which will be described later. A perspective in a case where the electrostatic chuck 10 is viewed from the surface 110 side along a direction perpendicular to the surface 110 will also be hereinafter expressed as "top view".

An attraction electrode 130 is embedded inside the dielectric substrate 100. The attraction electrode 130 is a thin planar (plate-like) layer made of a metallic material such as, for example, tungsten, and is arranged so as to be parallel to the surface 110. As a material of the attraction electrode 130, molybdenum, platinum, palladium, and the like may be used in addition to tungsten. When a voltage is applied to the attraction electrode 130 from an outside via a feed line 410, an electrostatic force is generated between the surface 110 and the wafer W, and according to this, the wafer W is attracted and held. The single attraction electrode 130 may be provided as so-called a "monopolar" electrode as in the present embodiment, but may also include two attraction electrodes as so-called "bipolar" electrodes. The attraction electrode 130 corresponds to a "conductor layer" provided inside the dielectric substrate 100.

In FIG. 1, the feed line 410 is entirely illustrated in a simplified manner. A portion of the feed line 410 inside the dielectric substrate 100 is configured as an elongated via (hole) filled with a conductor, for example, and a feed terminal is provided at a lower end thereof. A portion of the feed line 410 penetrating the base plate 200 is a rod-shaped metal whose one end is connected to the above-described feed terminal. A through hole which is not illustrated in the drawing for inserting the metal is formed in the base plate 200. As a configuration of the feed line 410 for applying a voltage to the attraction electrode 130, various well-known configurations can be adopted in addition to the above-described configuration.

In addition to the above-described attraction electrode 130, an RF electrode 140 is embedded inside the dielectric substrate 100. The RF electrode 140 is provided as one of a pair of counter electrodes for generating plasma in the semiconductor manufacturing apparatus. The other of the counter electrodes is provided at a position on an upper side relative to the electrostatic chuck 10 in the semiconductor manufacturing apparatus. When high-frequency alternating-current voltage is applied between these counter electrodes, plasma is generated on the upper side of the wafer W and used for processing such as film deposition and etching on the wafer W.

Similarly to the attraction electrode 130, the RF electrode 140 is a thin planar layer made of a metallic material such as, for example, tungsten. As a material of the RF electrode 140, molybdenum, platinum, palladium, and the like may be used in addition to tungsten. The RF electrode 140 is embedded at a position closer to the surface 120 side than the attraction electrode 130. Similarly to the attraction electrode 130, the RF electrode 140 is arranged in parallel to the surface 110. The RF electrode 140 is a single electrode which is substantially circular in top view. In top view, a center of the RF electrode 140 matches a center of the dielectric substrate 100. The RF electrode 140 corresponds to another "conductor layer" provided inside the dielectric substrate 100. In the present embodiment, a plurality of conductor layers including the attraction electrode 130 and the RF electrode 140 are provided at height positions different from each other.

A feed line 420 is connected to the RF electrode 140. The feed line 420 constitutes an electric circuit for applying a voltage to the RF electrode 140 from the outside. In FIG. 1, the feed line 420 is entirely illustrated in a simplified manner. A portion of the feed line 420 inside the dielectric substrate 100 is configured as an elongated via (hole) filled with a conductor, for example, and a feed terminal is provided at a lower end thereof. A portion of the feed line 420 penetrating the base plate 200 is a rod-shaped metal whose one end is connected to the above-described feed terminal. A through hole which is not illustrated in the drawing for inserting the metal is formed in the base plate 200. As a configuration of the feed line 420 for applying a voltage to the RF electrode 140, various well-known configurations can be adopted in addition to the above-described configuration.

As illustrated in FIG. 1, a space SP is formed between the dielectric substrate 100 and the wafer W. When a process such as etching is performed in the semiconductor manufacturing apparatus, a helium gas for temperature regulation is supplied to the space SP from the outside via a gas hole which is not illustrated in the drawing. When the helium gas is caused to be present between the dielectric substrate 100 and the wafer W, a thermal resistance between the dielectric substrate 100 and the wafer W is regulated, and according to this, a temperature of the wafer W is maintained at an appropriate temperature. It is noted that the gas for temperature regulation to be supplied to the space SP may be a gas of a type different from helium.

A seal ring 111 and a dot 112 are provided on the surface 110 which serves as the placement surface, and the space SP described above is formed around the seal ring 111 and the dot 112.

The seal ring 111 is a wall which defines the space SP in a position corresponding to an outermost circumference. The seal ring 111 is an annular protrusion formed on the surface 110 side. A distal end (upper end in FIG. 1) of the seal ring 111 is a part of the surface 110 and abuts against the wafer W. It can be mentioned that the distal end of the seal ring 111 is an outermost circumferential part of the surface 110 serving as the placement surface.

It is noted that the seal ring 111 may include a plurality of seal rings 111 provided so as to divide the space SP. With such a configuration, a pressure of the helium gas in each of the spaces SP can be individually regulated, and a surface temperature distribution of the wafer W during the process can be set to be close to uniformity.

A part denoted by reference sign "116" in FIG. 1 is a bottom of the space SP. Hereinafter, this part may also be referred to as a "bottom 116". The seal ring 111 is formed as a result of digging a part of the surface 110 to a position of the bottom 116 together with the dot 112 which will be described next.

The dot 112 is a circular protrusion which protrudes from the bottom 116. The dot 112 includes a plurality of dots 112 to be provided. The plurality of dots 112 are substantially uniformly distributed and arranged on the placement surface of the dielectric substrate 100. A distal end of each of the dots 112 is a part of the surface 110 and abuts against the wafer W. By providing the plurality of thus configured dots 112, warping of the wafer W is reduced.

In order that the helium gas supplied from a gas hole which is not illustrated in the drawing be rapidly supplied to each part of the space SP, a groove may be formed in the bottom surface 116. It is preferable that the groove be formed to pass through a position of the gas hole.

Additionally, after forming a plurality of gas holes in the dielectric substrate 100, a distribution flow path for distributing the helium gas to the respective gas holes may be formed inside the electrostatic chuck 10. The distribution flow path may be formed as a groove on the surface 120 of the dielectric substrate 100, or may be formed as a groove on a surface 210 of the base plate 200, which will be described next, and may also be formed inside the base plate 200.

The base plate 200 is a substantially disk-shaped member which supports the dielectric substrate 100. The base plate 200 is formed of a material containing aluminum nitride (AlN) as a principal component, and is joined to the dielectric substrate 100. The surface 210 on the upper side in FIG. 1 in the base plate 200 serves as a "surface to be joined" which is joined to the surface 120 of the dielectric substrate 100.

The surface 120 of the dielectric substrate 100 is joined to the surface 210 of the base plate 200 by solid-phase joining in the present embodiment. The term "solid-phase joining" refers to a joining method in which two members are joined while being pressurized and heated in a state where surfaces to be joined of the two members are brought into direct contact with each other, or are caused to abut against each other via a solid-phase joining material interposed therebetween. However, a temperature during heating is lower than melting points of the respective members and the joining material. Accordingly, during joining, the respective members and the joining material remain in a solid phase and do not become a liquid phase.

As a method for solid-phase joining, various well-known methods can be used. For example, after bringing the surface 120 of the dielectric substrate 100, which is a sintered body, and the surface 210 of the base plate 200, which is also a sintered body, into a state where they directly abut against each other or abut against each other via a joining material, the surface 120 and the surface 210 can be joined to each other by solid-phase joining by performing processing of heating and pressurizing so as to reach predetermined temperature and pressure. This processing is performed in a vacuum or under a reducing atmosphere. During the processing, temperatures of the dielectric substrate 100 and the base plate 200 may be set to be lower than their respective sintering temperatures.

In the present embodiment, the surface 120 of the dielectric substrate 100 is solid-phase joined to the surface 210 of the base plate 200 in a state where they directly abut against each other without interposing another joining material therebetween. Molecules constituting the base plate 200 have entered a portion of the dielectric substrate 100 in the vicinity of the surface 120 by solid-phase diffusion. Additionally, molecules constituting the dielectric substrate 100 have entered a portion of the base plate 200 in the vicinity of the surface 210 by solid-phase diffusion. Such solid-phase diffusion of molecules as described above may occur bidirectionally between the dielectric substrate 100 and the base plate 200, but may occur in only one direction. In this manner, by causing solid-phase diffusion of molecules beyond the surfaces to be joined in one direction or in both directions, the dielectric substrate 100 and the base plate 200 are firmly joined to each other. Such a joining aspect is also referred to as "diffusion joining".

In this manner, in the present embodiment, the dielectric substrate 100 and the base plate 200 are joined to each other by solid-phase joining. As compared with a case where they are joined to each other via a resin material, it is possible to enhance durability of a joined portion against plasma. Additionally, as compared with a case where they are joined to each other via a resin material, it is possible to enhance thermal conductivity.

A coolant flow path 250 through which a coolant flows is formed inside the base plate 200. When the process such as etching is performed in the semiconductor manufacturing apparatus, the coolant is supplied from the outside to the coolant flow path 250, and according to this, the base plate 200 is cooled down. Heat generated in the wafer W during the process is transferred to the coolant via the helium gas in the space SP, the dielectric substrate 100, and the base plate 200, and the heat is exhausted to the outside together with the coolant. The supply and exhaustion of the coolant to and from the coolant flow path 250 are performed via openings which are not illustrated in the drawing and which are formed in a surface 220 opposite to the surface 210 in the base plate 200.

The base plate 200 is configured by combining a first member 201 and a second member 202. The first member 201 and the second member 202 are joined to each other by the above-described diffusion joining, for example. In FIG. 1, a joining interface between the first member 201 and the second member 202 is indicated by a dotted line DL. The base plate 200 may be configured by joining three or more members to each other.

The coolant flow path 250 is a groove that has been formed in advance, before both members are joined to each other, along a front surface of the second member 202 which abuts against the first member 201 (a surface on the upper side in FIG. 1). In this manner, by forming the groove in the front surface of the second member 202 in advance and joining the first member 201 so as to cover the front surface, the coolant flow path 250 along the groove can be easily formed inside the base plate 200. The distribution flow path for gas described above may also be formed inside the base plate 200 by a similar method.

In an electrostatic chuck in the related art, a metallic material such as aluminum has been typically used as a material of the base plate 200, for example. The metallic material is a material having a relatively high thermal conductivity, so that the dielectric substrate 100 can be efficiently cooled by a coolant passing through the coolant flow path 250.

However, the metallic material is a material having a larger coefficient of linear expansion as compared with the ceramics material constituting the dielectric substrate 100. Due to this, when a temperature of the electrostatic chuck 10 increases or decreases in the semiconductor manufacturing apparatus, there is a possibility that peeling occurs between the dielectric substrate 100 and the base plate 200 due to a difference in coefficients of linear expansion. Particularly in recent semiconductor manufacturing apparatuses, in order to meet requirements such as multilayering, etching processing has come to be performed in an extremely low-temperature environment. For this reason, it is considered that the above-described peeling problem will become even more likely to occur in the future.

Thus, in the electrostatic chuck 10 according to the present embodiment, as described above, a material containing aluminum nitride (AlN) as a principal component is used as the material of the base plate 200 instead of the metallic material.

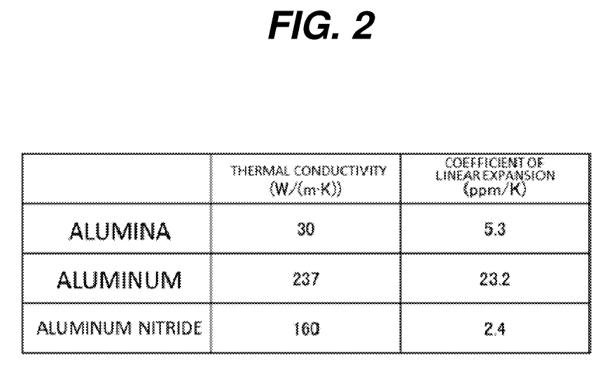

FIG. 2 illustrates respective physical properties (a thermal conductivity and a coefficient of linear expansion) of alumina, aluminum, and aluminum nitride. As illustrated in FIG. 2, a thermal conductivity of aluminum nitride is 160 W/(m⋅K), which is substantially equal to a thermal conductivity of aluminum (237 W/(m⋅K)). A coefficient of linear expansion of aluminum nitride is 2.4×10⁻⁶ /K, which is substantially equal to a coefficient of linear expansion of alumina (5.3×10⁻⁶ /K).

As described above, aluminum nitride is a material having a thermal conductivity substantially equal to that of aluminum, but its coefficient of linear expansion is substantially equal to that of alumina. By using, as the material of the base plate 200, aluminum nitride as described above in place of the metallic material as in the related art, it is possible to suppress peeling between the dielectric substrate 100 and the base plate 200 without sacrificing cooling performance of the base plate 200.

By adopting aluminum nitride as the material of the base plate 200, a thermal expansion difference between the dielectric substrate 100 and the base plate 200 becomes significantly smaller as compared with the related art. Due to this, even without interposing a joining layer made of an elastic material such as silicone between the dielectric substrate 100 and the base plate 200, it is possible to suppress peeling therebetween.

To further reduce the thermal expansion difference between the dielectric substrate 100 and the base plate 200, it is also conceivable to form both the dielectric substrate 100 and the base plate 200 using a material containing aluminum nitride as a principal component. However, aluminum nitride is a material having larger manufacturing constraints than alumina, for example, in that atmospheric firing cannot be performed. Due to this, in arranging a conductor layer inside the dielectric substrate 100, it is difficult to adjust a height position and a shape thereof with accuracy comparable to that in the related art. Additionally, it is considered that accuracy required for the dielectric substrate 100 will become even higher in the future with advancement of semiconductor manufacturing technology. Accordingly, as the material of the dielectric substrate 100, it is preferable to use alumina as in the present embodiment.

As in the present embodiment, in a case where a ceramic material is used as the material of the base plate 200 instead of the metallic material, the base plate 200 cannot be used as one of a pair of RF electrodes (a lower electrode). Thus, as in the present embodiment, the RF electrode 140 needs to be provided inside the dielectric substrate 100. It is also conceivable to provide the RF electrode 140 inside the base plate 200 made of a ceramic material. However, in such a case, a distance between an upper electrode, which is the other one of the RF electrodes, and the RF electrode 140 becomes excessively large, and there is a concern that controllability of plasma may deteriorate. Due to this, from a viewpoint of plasma controllability, it is preferable to provide the RF electrode 140 inside the dielectric substrate 100.

That is, in a case of using a ceramic material as the material of the base plate 200 instead of the metallic material, it is necessary to provide a plurality of conductor layers including at least the attraction electrode 130 and the RF electrode 140 inside the dielectric substrate 100. Also in view of this point, as the material of the dielectric substrate 100, it is preferable to use alumina, which is excellent in sinterability, instead of aluminum nitride.

A second embodiment will be described. In the following, features different from those of the first embodiment will be mainly described, and description of features common to those of the first embodiment is omitted as appropriate.

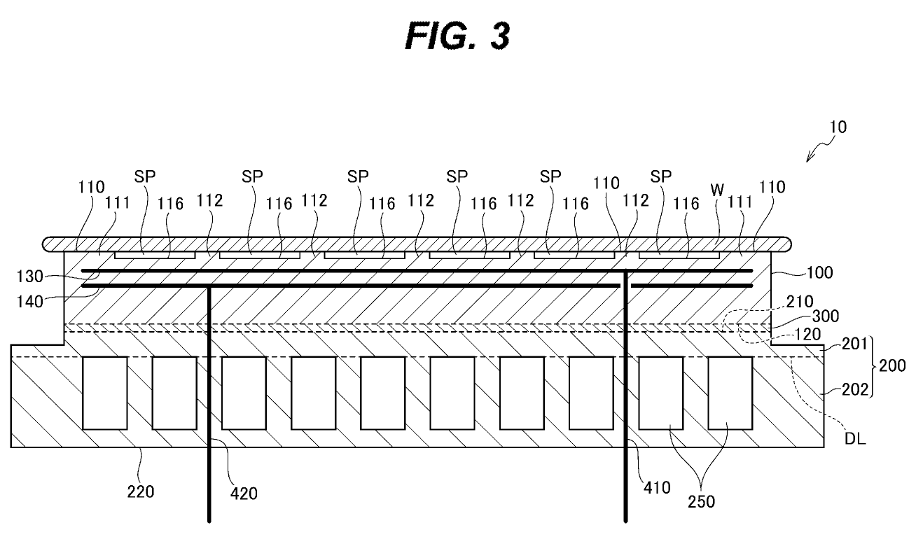

As illustrated in FIG. 3, in the electrostatic chuck 10 according to the present embodiment, the dielectric substrate 100 and the base plate 200 are joined to each other via a joining layer 300. The joining layer 300 is a layer that connects the dielectric substrate 100 and the base plate 200 to each other by solid-phase joining.

For example, the joining layer 300 as described above may be one that has resulted from mutual movement of molecules when the above-described processing of pressurizing and heating is performed in a state where the surface 120 of the dielectric substrate 100, which is a sintered body, and the surface 210 of the base plate 200, which is also a sintered body, are caused to directly abut against each other. Alternatively, the joining layer 300 may be one that has resulted from the above-described processing of pressurizing and heating in a state where some joining material is interposed between the surface 120 and the surface 210, instead of directly causing the surface 120 and the surface 210 to abut against each other.

The joining layer 300 is a composite material including both alumina as the material of the dielectric substrate 100 and aluminum nitride as the material of the base plate 200. The joining layer 300 may further contain a material different from alumina and aluminum nitride.

By joining the dielectric substrate 100 to the base plate 200 via the joining layer 300 made of such a material, it is possible to further increase joining strength at respective joining interfaces. Furthermore, since physical property values of the joining layer 300 (specifically, a coefficient of linear expansion, a thermal conductivity, and the like) can be set to values intermediate between physical property values of the dielectric substrate 100 and physical property values of the base plate 200, an effect can also be obtained in that thermal stress of each part when used in a low-temperature environment or the like can be further alleviated.

The alumina content and the aluminum nitride content in respective parts of the joining layer 300 may be uniform over the entire joining layer 300. However, in the present embodiment, the content of each element is made different for each location. Herein, the term "content" refers to a ratio of the number of molecules contained per unit volume of the joining layer 300, for example.

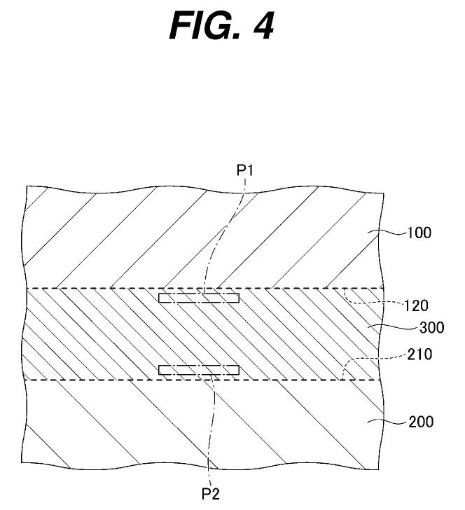

FIG. 4 illustrates an enlarged view of a configuration of the joining layer 300 and a portion in the vicinity thereof in FIG. 3. A first portion P1 illustrated in FIG. 4 is a portion of the joining layer 300 on the dielectric substrate 100 side, specifically, a portion in the vicinity of the surface 120. A second portion P2 is a portion of the joining layer 300 on the base plate 200 side, specifically, a portion in the vicinity of the surface 210.

In the joining layer 300 of the present embodiment, an alumina content in the first portion P1 is larger than an alumina content in the second portion P2. Additionally, an aluminum nitride content in the second portion P2 is larger than an aluminum nitride content in the first portion P1.

In such a configuration, a physical property value of the first portion P1 of the joining layer 300, which is close to the dielectric substrate 100, can be made closer to a physical property value of the dielectric substrate 100. Furthermore, a physical property value of the second portion P2 of the joining layer 300, which is close to the base plate 200, can be made closer to a physical property value of the base plate 200. As a result, for example, it is possible to further alleviate thermal stress of each part when used in a low-temperature environment.

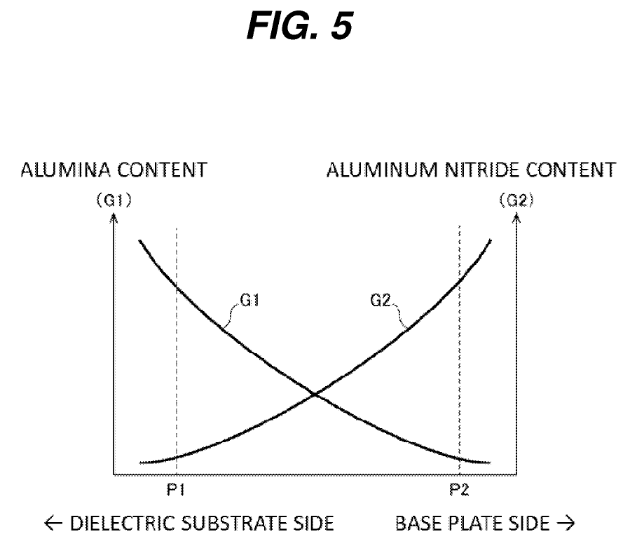

A horizontal axis of a graph illustrated in FIG. 5 represents coordinates of respective parts of the joining layer 300 along a direction perpendicular to the placement surface (an up and down direction in FIGS. 3 and 4). In FIG. 5, the horizontal axis is set such that a position becomes closer to the dielectric substrate 100 toward a left side, and becomes closer to the base plate 200 toward a right side.

A line G1 illustrated in FIG. 5 represents a distribution of the alumina content in respective parts of the joining layer 300. A line G2 represents a distribution of aluminum nitride content in respective parts of the joining layer 300. As illustrated in FIG. 5, the contents in the respective parts are distributed so as to change smoothly in accordance with a change in coordinates on the horizontal axis.

Specifically, an alumina content (line G1) in the joining layer 300 gradually decreases from the dielectric substrate 100 side toward the base plate 200 side. Additionally, an aluminum nitride content (line G2) in the joining layer 300 gradually decreases from the base plate 200 side toward the dielectric substrate 100 side. As a result, the alumina content in the first portion P1 is larger than the alumina content in the second portion P2, and the aluminum nitride content in the second portion P2 is larger than the aluminum nitride content in the first portion P1. By distributing the respective contents so as to change smoothly, it is possible to prevent a situation in which a large local stress occurs.

The joining layer 300 as described above may be formed in advance as a plate-shaped member in which alumina content and aluminum nitride content are distributed as described above, and the member may thereafter be interposed between the dielectric substrate 100 and the base plate 200 to be solid-phase joined. Alternatively, in a state where a plate-shaped or powder-shaped member in which alumina and aluminum nitride are each uniformly distributed may be interposed between the dielectric substrate 100 and the base plate 200, the entirety thereof may be solid-phase joined by performing processing of pressurizing and heating for a predetermined time. In this case, as a result of occurrence of solid-phase diffusion between the dielectric substrate 100 and the plate-shaped member or the like, and occurrence of solid-phase diffusion between the base plate 200 and the plate-shaped member or the like, respectively, it is possible to obtain the joining layer 300 in which contents of the respective materials are distributed as in FIG. 5.

Depending on conditions and methods of solid-phase joining, there may be both a case where a boundary between the joining layer 300 and the dielectric substrate 100 or the like can be clearly visually recognized, and a case where it cannot be clearly visually recognized. Similarly to the first embodiment, there may be a case where the joining layer 300 itself cannot be clearly visually recognized.

In a case where a boundary of the joining layer 300 or the joining layer 300 itself cannot be clearly visually recognized, it is possible to confirm whether the dielectric substrate 100 and the base plate 200 are joined by solid-phase joining by cutting out a sample so as to include both a portion that is clearly the dielectric substrate 100 (that is, alumina) and a portion that is clearly the base plate 200 (that is, aluminum nitride), and analyzing a portion therebetween. The analysis can be performed by using a well-known elemental analysis method such as EDX analysis, for example.

For example, in a case where it is confirmed that no elements other than Al, O, and N are present at the joining interface between the dielectric substrate 100 and the base plate 200, it is strongly presumed that solid-phase joining has been performed in a state where the surface 120 and the surface 210 are caused to directly abut against each other. Additionally, in a case where other elements are present in addition to Al, O, and N at the above-described joining interface, it is strongly presumed that solid-phase joining has been performed in a state where some joining material is interposed between the surface 120 and the surface 210.

Furthermore, in a case where it is confirmed that an amorphous layer is present at the above-described joining interface by X-ray diffraction, it is strongly presumed that the dielectric substrate 100 and the base plate 200 are joined to each other by solid-phase joining.

A third embodiment will be described. In the following, features different from those of the above-described second embodiment will be mainly described, and description of features common to those of the second embodiment is omitted as appropriate.

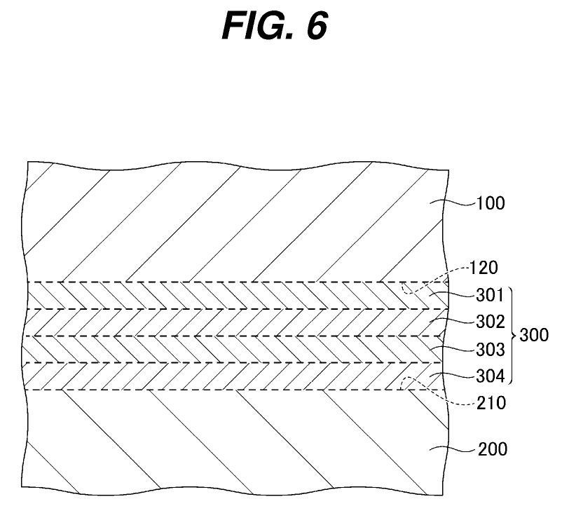

FIG. 6 illustrates an enlarged view of a configuration of the joining layer 300 and a portion in the vicinity thereof. As illustrated in FIG. 6, the joining layer 300 of the present embodiment includes a plurality of layers that are laminated along the direction perpendicular to the placement surface. These layers include a first layer 301, a second layer 302, a third layer 303, and a fourth layer 304 in order from the dielectric substrate 100 side. A total number of layers constituting the joining layer 300 may be three or less, or five or more.

Adjacent ones of the layers constituting the joining layer 300 are joined to each other by solid-phase joining. Additionally, the first layer 301 and the dielectric substrate 100, and the fourth layer 304 and the base plate 200 are also joined to each other by solid-phase joining.

Inside the respective layers constituting the joining layer 300, the alumina content is substantially uniform in the entire layer, and the aluminum nitride content is also substantially uniform in the entire layer. However, the alumina content in the second layer 302 is smaller than the alumina content in the first layer 301, the alumina content in the third layer 303 is smaller than the alumina content in the second layer 302, and the alumina content in the fourth layer 304 is smaller than the alumina content in the third layer 303. The aluminum nitride content in the third layer 303 is smaller than the aluminum nitride content in the fourth layer 304, the aluminum nitride content in the second layer 302 is smaller than the aluminum nitride content in the third layer 303, and the aluminum nitride content in the first layer 301 is smaller than the aluminum nitride content in the second layer 302.

As described above, the alumina content in the joining layer 300 of the present embodiment decreases in a stepwise manner from the dielectric substrate 100 side toward the base plate 200 side, and the aluminum nitride content in the joining layer 300 decreases in a stepwise manner from the base plate 200 side toward the dielectric substrate 100 side. As a result, the alumina content in a portion corresponding to the first portion P1 in FIG. 4 is larger than the alumina content in a portion corresponding to the second portion P2, and the aluminum nitride content in the portion corresponding to the second portion P2 is larger than the aluminum nitride content in the portion corresponding to the first portion P1. Also in such an aspect, an effect similar to that described in the second embodiment can be exhibited.

Alternatively, it is possible to adopt an aspect in which each of the layers such as the first layer 301 constituting the joining layer 300 does not contain one or both of alumina and aluminum nitride. For example, each of the first layer 301 and the like may contain aluminum oxynitride (AlON) as a principal component. In this case, it is preferable that relative ratios of respective atoms (Al, O, and N) constituting aluminum oxynitride be made different for each layer constituting the joining layer 300. For example, materials of the respective layers may be adjusted such that the layer contains more oxygen atoms (O) as it is closer to the dielectric substrate 100, and the layer contains more nitrogen atoms (N) as it is closer to the base plate 200.

In the embodiments described above, an example of a case in which the dielectric substrate 100 and the base plate 200 are joined to each other by solid-phase joining has been described. The dielectric substrate 100 and the base plate 200 may be joined to each other by a method other than solid-phase joining. For example, they may be joined to each other by fusion welding using a laser or an electron beam.

The present embodiments have been described above with reference to the specific examples. However, the present disclosure is not limited to these specific examples. Configurations obtained by adding appropriate design modifications to these specific examples by a person skilled in the art are also within the scope of the present disclosure as long as the configurations have a feature of the present disclosure. Each of the elements included in each of the specific examples described above and arrangements, conditions, shapes, and the like of the elements are not limited to those illustrated and can be modified as appropriate. For each of the elements included in each of the specific examples described above, a combination can be appropriately changed as long as a technical contradiction does not occur.

What is claimed is:

1. An electrostatic chuck comprising:
a dielectric substrate including a placement surface on which an object to be attracted is placed; and
a base plate joined to the dielectric substrate, wherein
the dielectric substrate is formed of a material containing alumina as a principal component, and
the base plate is formed of a material containing aluminum nitride as a principal component.

2. The electrostatic chuck according to claim 1, wherein the dielectric substrate and the base plate are joined to each other by solid-phase joining.

3. The electrostatic chuck according to claim 2, wherein a joining layer is provided between the dielectric substrate and the base plate and connects the dielectric substrate and the base plate by solid-phase joining.

4. The electrostatic chuck according to claim 3, wherein the joining layer contains both alumina and aluminum nitride.

5. The electrostatic chuck according to claim 4, wherein
with a portion of the joining layer on the dielectric substrate side being defined as a first portion, and
a portion of the joining layer on the base plate side being defined as a second portion,
an alumina content in the first portion is larger than an alumina content in the second portion, and
an aluminum nitride content in the second portion is larger than an aluminum nitride content in the first portion.

6. The electrostatic chuck according to claim 5, wherein
an alumina content in the joining layer gradually decreases from the dielectric substrate side toward the base plate side, and
an aluminum nitride content in the joining layer gradually decreases from the base plate side toward the dielectric substrate side.

7. The electrostatic chuck according to claim 5, wherein the joining layer includes a plurality of layers that are laminated along a direction perpendicular to the placement surface.

8. The electrostatic chuck according to claim 7, wherein
an alumina content in the joining layer decreases from the dielectric substrate side toward the base plate side, and
an aluminum nitride content in the joining layer decreases from the base plate side toward the dielectric substrate side.

9. The electrostatic chuck according to claim 3, wherein the joining layer includes a plurality of layers that are laminated along a direction perpendicular to the placement surface.

10. The electrostatic chuck according to claim 1, wherein the dielectric substrate contains highly pure alumina having a purity of 99.5% or more as a principal component.

11. The electrostatic chuck according to claim 1, wherein a conductor layer is provided inside the dielectric substrate.

12. The electrostatic chuck according to claim 11, wherein a plurality of the conductor layers are provided at height positions different from each other.
